(19) United States
(12) Patent Application Publication
(10) Pub. No.: US 2025/0221002 A1
(43) Pub. Date: Jul. 3, 2025

(54) AIRGAP SPACER WITH BACKSIDE POWER DELIVERY

(71) Applicant: International Business Machines Corporation, Armonk, NY (US)

(72) Inventors: Ruilong Xie, Niskayuna, NY (US); Reinaldo Vega, Mahopac, NY (US); Julien Frougier, Albany, NY (US); Andrew Gaul, Halfmoon, NY (US); Nicholas Anthony Lanzillo, Wynantskill, NY (US)

(21) Appl. No.: 18/400,523

(22) Filed: Dec. 29, 2023

(51) Int. Cl. H01L 29/417; H01L 23/528; H01L 29/06; H01L 29/423; H01L 29/775; H01L 29/786

(52) U.S. Cl. CPC H10D 64/258; H01L 23/5286; H10D 30/43; H10D 30/6735; H10D 30/6757; H10D 62/121; H10D 64/254

(57) ABSTRACT

A semiconductor device includes a gate structure on a stack of channel layers, a source/drain region adjacent to the stack of channel layers, and an inner airgap spacer positioned between channels in the stack of channel layers. The inner airgap spacer separates the gate structure from the source/drain region. The semiconductor device can further include a backside interface layer across a base of the inner airgap spacer.

### BACKGROUND

The present disclosure relates to semiconductor devices, and more particularly to semiconductor devices including airgap spacers.

Modern integrated circuits are made up of active devices including transistors. Field effect transistors (FETs) are widely used in the electronics industry for switching, amplification, filtering and other tasks related to both analog and digital electrical signals. Most common among these are metal oxide semiconductor field effect transistors (MOSFET or MOS), in which a gate structure is energized to create an electric field in an underlying channel region of a semiconductor body, by which electrons are allowed to travel through the channel between a source region and a drain region of the semiconductor body.

Vertically stacked devices are a form of a field effect transistor that provides for increased device integration and improved scaling. However, with increased scaling certain difficulties have arisen. For example, as device scaling increases spacing between conductive and insulating features decreases resulting in parasitic capacitance. These capacitances have a direct impact in the speed of operation of field effect transistor circuits. Therefore, in order to increase the speed of operation, the incidence of parasitic capacitances should be reduced to a minimum.

Reducing the parasitic capacitance between a gate metal and a source/drain contact of a transistor can decrease device switching delays. One way to reduce parasitic capacitance is to reduce the effective dielectric constant of material layers between the gate and source/drain. This can be done by creating airgaps in the dielectric material at that location.

However, when considering the processing of stacked channel devices, frontside integration of airgaps is particularly problematic due to the complexity of the device structures.

Therefore, a need exists for airgaps introduced without requiring integration via frontside processing.

### SUMMARY

In accordance with embodiments of the present invention, airgaps may be integrated into stacked channel semiconductor devices using backside processing. More particularly, a backside interface layer may be employed in combination with a fill dielectric to encapsulate an airgap from a backside of the device after the active devices have been formed. The airgap can include an inner airgap spacer between channel layers in a channel layer stack. The airgap can further include a gate sidewall airgap spacer. The airgap can also include a source/drain airgap spacer.

In an embodiment, the semiconductor device includes a gate structure on a stack of channel layers, and a source/drain region adjacent to the stack of channel layers. The semiconductor device also includes an inner airgap spacer positioned between channels in the stack of channel layers. The inner airgap spacer separates the gate structure from the source/drain region. The semiconductor device may also include a backside interface layer across a base of the inner airgap spacer.

In some embodiments, the gate structure can be a gate all around gate structure. In some embodiments, a first side of the inner airgap spacer is in contact with the gate structure, and a second side of the inner airgap spacer is in contact with the source/drain region. In one example, the source/drain region has a frontside contact. A backside contact to the source/drain region may extend to a backside power distribution network.

In another embodiment, the semiconductor device includes a gate structure on a stack of channel layers, a source/drain region adjacent to the stack of channel layers, and an inner airgap spacer positioned between channels in the stack channel layers. The inner airgap spacer separates the gate structure from the source/drain region. In an embodiment, a backside interface layer extends across a base of the inner airgap spacer. The semiconductor device can also include a gate sidewall airgap spacer present on a sidewall of the gate structure that is overlying the inner airgap spacer.

In some embodiments, the gate structure is a gate all around gate structure. In one example, a first side of the inner airgap is in contact with the gate structure, and a second side of the inner airgap is in contact with the source/drain region. In an embodiment, the source/drain region has a frontside contact. A backside contact to the source/drain region may extend to a backside power distribution network.

In an embodiment, the semiconductor device includes a gate structure on a stack of channel layers, a source/drain region adjacent to the stack of channel layers, and an inner airgap spacer positioned between channels in the stack of channel layers. The inner airgap spacer separates the gate structure from the source/drain region. The semiconductor device can include a backside interface layer across a base of the inner airgap spacer. In some embodiments, the semiconductor device can include a source/drain airgap spacer present on a face of the source/drain region.

In an embodiment, the gate structure is a gate all around gate structure. In one example, a first side of the inner airgap spacer is in contact with the gate structure and a second side of the inner airgap spacer is in contact with the source/drain region. In some embodiments, the source/drain region can include a frontside contact. In some embodiments, a backside contact to the source/drain region may extend to a backside power distribution network.

In an embodiment, a semiconductor device includes a gate structure on a stack of channel layers, and a source/drain region adjacent to the stack of channel layers. The semiconductor device can also include an inner airgap spacer positioned between channels in the stack of channel layers, wherein the inner airgap spacer separates the gate structure from the source/drain region. The semiconductor device may further include a backside interface layer extending from a base surface of the channel layer stack to a base surface of the source/drain regions to encapsulate the inner airgap spacer. In an embodiment, the gate structure is a gate all around gate structure. In some embodiments, a gate sidewall airgap spacer is present on a sidewall of the gate structure that is overlying the inner airgap spacer.

In an embodiment, a semiconductor device includes a gate structure on a stack of channel layers, source/drain regions on opposing sides of the stack of channel layers, and inner airgap spacers positioned between channels in the stack of channel layers. The inner airgap spacers separate the gate structure from the source/drain regions. In an embodiment, the backside interface layer extends from the stack of channel layers to a first of the source/drain regions across a base of the inner gap spacers. The semiconductor device includes a backside contact to a second of the source/drain regions.

In an embodiment, the gate structure is a gate all around gate structure. In an embodiment, a gate sidewall airgap spacer is present on a sidewall of the gate structure that is overlying the inner airgap spacer. In an embodiment, a source/drain airgap spacer is present on a face of the source/drain regions. In an embodiment, the backside contact may extend to a backside power distribution network.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 is a top down view of a semiconductor device having airgaps produced using backside processing, in which the top down view illustrates the relationship between cross-section lines identified by X-X, Y1-Y1 and Y2-Y2 for each of the side-cross sectional figures provided herein, in accordance with an embodiment of the present invention;

FIG. 2 is a side cross-sectional view along section line X-X of FIG. 1 showing a completed structure of a semiconductor device including an inner airgap spacer and a gate sidewall airgap spacer, in accordance with an embodiment of the present invention;

FIG. 3 is a side cross-sectional view along section line Y1-Y1 of FIG. 1, in which the cross-section extends through an inner airgap spacer, in accordance with an embodiment of the present invention;

FIG. 4 is a side cross-sectional view along section line Y2-Y2 of FIG. 1 showing a source/drain airgap spacer, in accordance with an embodiment of the present invention;

FIG. 5 is a side cross-sectional view along section line Y1-Y1 of an initial semiconductor device structure that can be used in an embodiment of a method for forming airgaps using backside processing, in accordance with an embodiment of the present invention;

FIG. 6 is a side cross-sectional view along section line Y1-Y1 depicting active region patterning of the starting structure depicted in FIG. 5 followed by depositing an interlevel dielectric material, in accordance with an embodiment of the present invention;

FIG. 7 is a side cross-sectional view along section line Y1-Y1 depicting forming a backside interface layer, in accordance with an embodiment of the present invention;

FIG. 8 is a side cross-sectional view along section line Y1-Y1 depicting deposition of an interlevel dielectric layer (ILD) on the structure depicted in FIG. 7 followed by a etch process to reveal channel layers, in accordance with an embodiment of the present invention;

FIG. 9 is a side cross-sectional view along section line X-X depicted forming a replacement gate structure, forming a sacrificial gate spacer, forming a sacrificial inner spacer and forming source/drain regions to the structure depicted in FIG. 8, in accordance with an embodiment of the present invention;

FIG. 10 is a side cross-sectional view along section line Y1-Y1 of the structure depicted in FIG. 9 illustrating the sacrificial inner spacer, in accordance with an embodiment of the present invention;

FIG. 11 is a side cross-sectional view along section line Y2-Y2 of the structure depicted in FIG. 9 illustrating a sacrificial source/drain spacer, in accordance with an embodiment of the present invention;

FIG. 12 is a side cross-sectional view along section line X-X of the structure depicted in FIG. 9 showing a replacement gate process to provide a functional gate structure, in accordance with an embodiment of the present invention;

FIG. 13 is a side cross-sectional view along section line Y1-Y1 of the structure depicted in FIG. 12 showing a sacrificial inner spacer, in accordance with an embodiment of the present invention;

FIG. 14 is a side cross sectional view along section line Y2-Y2 depicting a frontside contact to the source/drain regions, in accordance with an embodiment of the present invention;

FIG. 15 is a side cross-sectional view along section line X-X of the structure depicted in FIG. 12 illustrating formation of backside contacts to source/drain regions, in accordance with an embodiment of the present invention;

FIG. 16 is a side cross-sectional view along section line Y1-Y1 of the structure depicted in FIG. 15 illustrating formation of backside contacts to source/drain regions, in accordance with an embodiment of the present invention;

FIG. 17 is a side cross sectional view along section line Y2-Y2 of the structure depicted in FIG. 15 depicting formation of a backside contact to the source/drain regions, in accordance with an embodiment of the present invention;

FIG. 18 is a side cross-sectional view along section line Y1-Y1 illustrating removing the sacrificial inner spacer and the sacrificial gate sidewall spacer, in accordance with an embodiment of the present invention;

FIG. 19 is a side cross-sectional view along section line X-X of the structure depicted in FIG. 18 illustrating removing the sacrificial inner spacer, in accordance with an embodiment of the present invention;

FIG. 20 is a side cross-sectional view along section line Y2-Y2 of the structure depicted in FIG. 18 depicting the removal of the sacrificial source/drain spacer, in accordance with an embodiment of the present invention;

FIG. 21 is a side cross-sectional view along section line Y1-Y1 of the structure depicted in FIG. 18 illustrating a sealing dielectric deposition to seal openings to the inner airgap spacer and gate sidewall airgap spacer, in accordance with an embodiment of the present invention;

FIG. 22 is a side cross-sectional view along section line X-X of the structure depicted in FIG. 21 illustrating formation of the inner airgap spacer, in accordance with an embodiment of the present invention; and

FIG. 23 is a side cross-sectional view along section line Y2-Y2 of the structure depicted in FIG. 21 depicting formation of the source/drain airgap spacer, in accordance with an embodiment of the present invention.

### DETAILED DESCRIPTION

Detailed embodiments of the claimed methods and structures are described herein; however, it is to be understood that the described embodiments are merely illustrative of the claimed structures and methods that may be embodied in various forms. In addition, each of the examples given in connection with the various embodiments are intended to be illustrative, and not restrictive. Further, the figures are not necessarily to scale, some features may be exaggerated to show details of particular components. Therefore, specific structural and functional details described herein are not to be interpreted as limiting, but merely as a representative basis for teaching one skilled in the art to variously employ the methods and structures in accordance with embodiments of the present invention.

The methods and structures described herein can reduce parasitic capacitance in field effect transistor devices. These capacitances have a direct impact in the speed of operation of field effect transistor circuits. Reducing the parasitic capacitance can decrease device switching delays. One way to reduce parasitic capacitance is to reduce the effective dielectric constant of the material between the gate structure and the source/drain regions. This can be done by creating airgaps in the dielectric material at locations between the gate structure and the source/drain regions. For example, the value of the dielectric constant of air at room temperature (25° C., or 77° F.) is 1.00059, which is significantly less than the dielectric constant of solid spacer dielectric materials, such as silicon oxide. However, when considering the processing of stacked channel devices, frontside integration of airgaps is particularly problematic due to the complexity of the device structures. In some embodiments, a mechanism for introducing inner airgap spacers is provided without requiring integration via frontside processing.

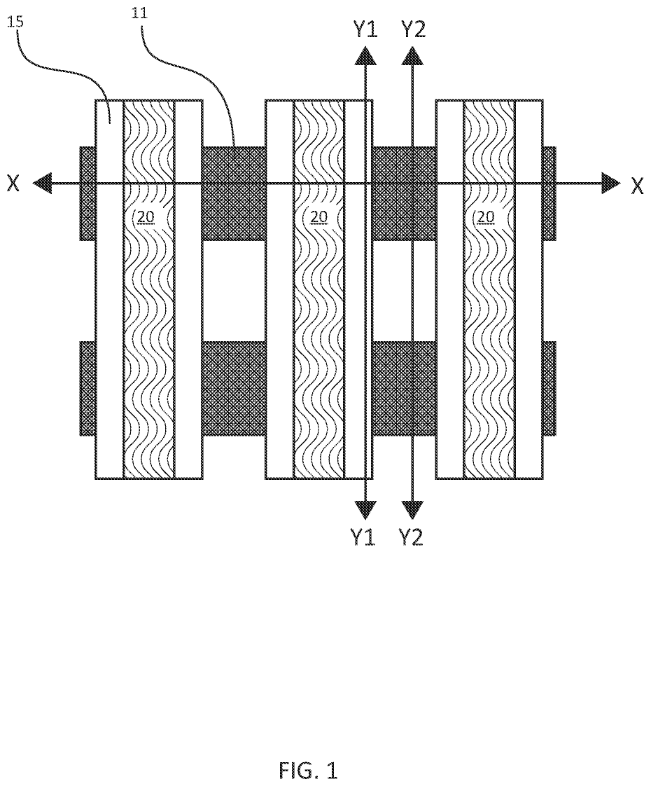

Referring now to the drawings in which like numerals represent the same or similar elements and initially to FIG. 1, a top down view of a semiconductor device is depicted having an airgap produced with backside processing. The top down view depicted in FIG. 1 illustrates the relationship between cross-section lines identified by X-X, Y1-Y1 and Y2-Y2 for each of the side-cross sectional figures provided herein.

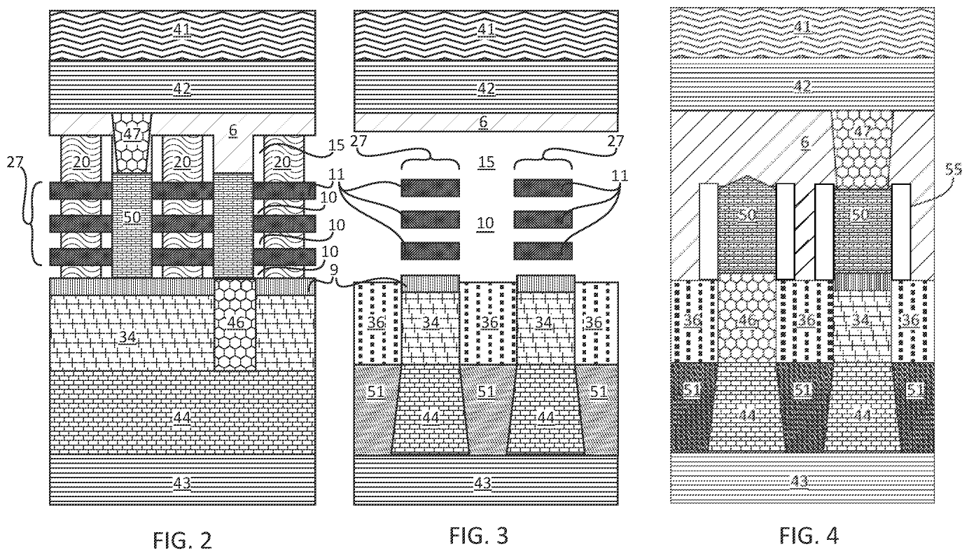

FIG. 2 is a side cross-sectional view along section line X-X of FIG. 1 showing one embodiment of a semiconductor device including an inner airgap spacer 10. The semiconductor device includes a gate structure 20 on a stack of channels 27 and source/drain regions 50 adjacent to the stack of channels 27. The inner airgap spacer 10 is positioned between individual channel layers 11 in the stack of channels 27. The inner airgap spacer 10 also separates the gate structure 20 from the source/drain regions 50. The inner airgap spacer 10 is present on each side of the gate structure 20.

The channel layers 11 in the stack of channels 27 may be two-dimensional nanostructures with a thickness ranging from between about 1 nm to about 100 nm. In one example, the channel layers 11 have a composition that includes a type IV semiconductor, such as silicon (Si), germanium (Ge) and/or silicon germanium (SiGe). The channel layers 11 may also be provided by a type III-V semiconductor material, such as gallium arsenide (GaAs).

The gate structure 20 is in direct contact with the channel layers 11 in the stack of channels 27. A “gate structure” is a structure used to control output current (e.g., flow of carriers in the channel) of a semiconducting device, such as a field effect transistor (FET). The gate structure 20 can include a high-k gate dielectric, and a metal gate conductor, which may be referred to as a high-k metal gate (HKMG). In some embodiments, the gate structure 20 may be a gate all around (GAA) device. The term “gate all around (GAA)” denotes a gate structure 20 that encloses the channel layers 11 from both a frontside and backside of the channel. In some instances, the gate all around (GAA) structure may include a conformal gate dielectric layer (not shown) that has the composition of a high-k gate dielectric material, and a gate conductor of an elemental metal (which may be referred to as a metal gate).

The source/drain regions 50 are present on opposing sides of the channel layers 11 in the stack of channels 27 and have a semiconductor composition. The source/drain regions 50 may be doped with an n-type or p-type dopant. As used herein, “p-type” refers to the addition of impurities to an intrinsic semiconductor that creates deficiencies of valence electrons. In a type IV semiconductor, such as silicon, examples of p-type dopants include but are not limited to, boron, aluminum, gallium and indium. As used herein, “n-type” refers to the addition of impurities that contributes free electrons to an intrinsic semiconductor. In a type IV semiconductor, such as silicon, examples of n-type dopants include but are not limited to antimony, arsenic and phosphorous.

In some embodiments, the epitaxial semiconductor material that provides the source/drain regions 50 may have a composition that includes silicon (Si), germanium (Ge), silicon germanium (SiGe), silicon doped with carbon (Si:C), or the epitaxial semiconductor material that provides the source/drain regions 50 may have a composition of a type III-V compound semiconductor, such as gallium arsenide (GaAs).

A metal gate conductor or gate electrode of the gate structure 20 and the source/drain regions 50 (as well as the contacts to the source/drain regions) are electrically conductive features. Dielectric elements are positioned therebetween. The combination of these electrically conductive and dielectric elements can result in parasitic capacitance that can negatively impact the switching speed of the semiconductor device. As the device size is scaled to lesser and lesser dimensions, the dielectric distance separating the aforementioned electrically conductive features is reduced, which increases parasitic capacitance. To reduce the parasitic capacitance, airgaps are substituted for the solid dielectric material that is separating the aforementioned electrically conductive features.

The airgap, such as the inner airgap spacer 10, is a space that is filled with air and is positioned between electrically conductive features. Air has a dielectric constant that at room temperature (25° C. or 77° F.) can be equal to 1.00059, which is significantly less than the dielectric constant of solid dielectric materials, such as silicon oxide.

Referring to FIG. 2, the inner airgap spacer 10 is positioned between the individual channel layers 11 in the stack of channels 27, and is present at the ends of the channel layers 11 between the gate structure 20 and the source/drain regions 50. More particularly, the inner airgap spacer 10 has a first side that is in contact with the gate structure 20, and a second side that is in contact with the source/drain region 50.

In some embodiments, the bottom of the inner airgap spacer 10 is separated from a backside interlevel dielectric layer 34 by a backside interface layer 9. In some embodiments, the backside interface layer 9 extends across a base of the inner airgap spacer 10. The backside interface layer 9 may be a dielectric material. In some embodiments, the dielectric material of the backside interface layer 9 encloses the space between the channel layers 11 at the bottom of the stack of channels 27, the gate electrode of the gate structure 20 and one of the source/drain regions 50. The backside interface layer 9 may be a continuous layer that extends from the base of the source/drain regions 50 to across the base of the inner airgap spacer 10 to the base of the gate structure 20.

Referring to FIG. 2, the backside interface layer 9 can separate the stack of channels 27 from a backside interlevel dielectric layer 34. In some embodiments, a backside contact 46 can extend through an opening in the backside interlevel dielectric layer 34 and extend through an opening through the backside interface layer 9 into electrical contact with a backside surface of one of the source/drain regions 50. The backside contact 46 extends from the backside of one of the source/drain regions 50 to a buried power rail 44, which is in electrical communication with a backside power distribution network 43. FIG. 2 also depicts a frontside contact 47 that extends from a back end of the line level 42 through a frontside interlevel dielectric layer 6 to a second of the source/drain regions 50.

Referring to FIG. 2, in an embodiment, the device also includes a gate sidewall airgap spacer 15. The gate sidewall airgap spacer 15 is present atop the inner airgap spacer 10. The gate sidewall airgap spacer 15 is present on an upper sidewall of the gate structure 20 and is present overlying the channel at the top of the stack of channels 27.

FIG. 3 is a side cross-sectional view along section line Y1-Y1 of FIG. 2. The cross-section depicted in FIG. 2 extends through an inner airgap spacer 10. FIG. 3 illustrates the channel layers 11 suspended in the air that is enclosed by the inner airgap spacer 10 and the gate sidewall airgap spacer 15.

FIG. 4 is a side cross-sectional view along section line Y2-Y2 of FIG. 1. FIG. 4 depicts an embodiment of a source/drain airgap spacer 55. In addition to the inner airgap spacer 10 and the gate sidewall airgap spacer 15, the source/drain airgap spacer 55 can be positioned on the face of the source/drain regions 50. The source/drain airgap spacer 55 is substituted for a higher dielectric constant spacer that is used during process steps for forming the epitaxial semiconductor material for the source/drain regions 50. Epitaxial semiconductor material is a grown material, and solid dielectric spacers can be employed to limit the lateral growth of epitaxial semiconductor material to ensure that the epitaxially grown material does not contact other electrically conductive features in the device causing a short. Substituting the source/drain airgap spacer 55 having a low-k dielectric constant for a solid dielectric spacer of a higher dielectric constant material can further reduce parasitic capacitances.

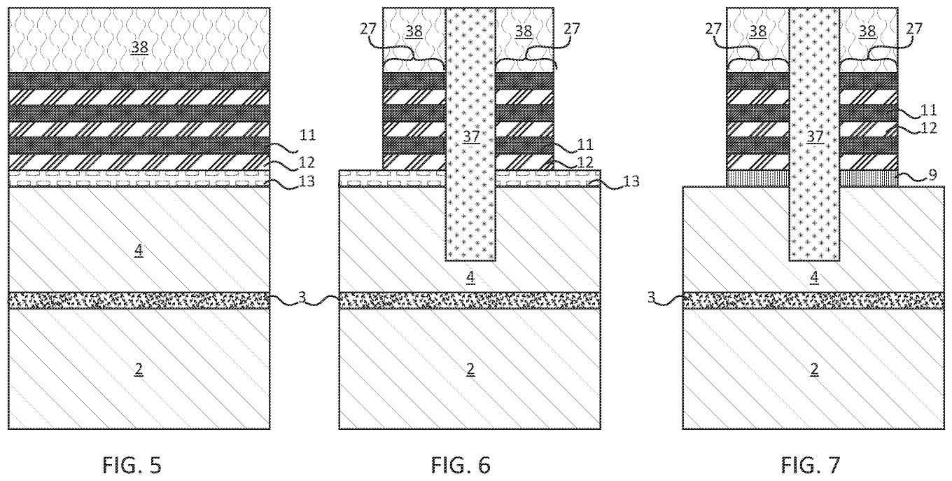

FIG. 5 illustrates one embodiment of an initial device structure that can be used in a method for forming the inner airgap spacer 10 using backside processing, in accordance with an embodiment of the present invention.

In some embodiments, the initial device structure can include a stack of the channel layers 11, a first sacrificial sheet 13 and second sacrificial sheets 12, in which the stack is present on an upper semiconductor layer 4, an etch stop layer 3 and a substrate 2. Each of the layers in the stack may include a type IV semiconductor composition that provides for etch selectivity relative to the subsequently formed backside interface layer 9. For example, the channel layers 11 may have a silicon composition, while the first sacrificial sheet 13 has a composition of silicon germanium (SiGe55) having 55% germanium (Ge) content. The second sacrificial sheets 12 can have a composition of silicon germanium (SiGe25) having 25% germanium (Ge) content. The upper semiconductor layer 4 may have a silicon composition, while the etch stop layer 3 can have a composition of silicon germanium (SiGe25) having 25% germanium (Ge) content. The substrate 2 can have a silicon containing composition. The channel layers 11, the first sacrificial sheet 13 and the second sacrificial sheets 12 may be formed using a deposition process, such as epitaxial deposition.

FIG. 6 is a side cross-sectional view along section line Y1-Y1 depicting patterning of the initial structure followed by depositing an interlevel dielectric material 37. In some embodiments, to pattern the active regions, a hardmask 38 may be formed atop the stack of the channel layers 11, the first sacrificial sheet 13 and the second sacrificial sheets 12. In some embodiments, the hardmask 38 may have a composition that includes a nitride, such as silicon nitride. For example, a pattern (not shown) is produced by applying a photoresist to the surface to be etched, exposing the photoresist to a pattern of radiation, and then developing the pattern into the photoresist utilizing a resist developer. Once the patterning of the photoresist is completed, the sections of the stack covered by the photoresist are protected while the exposed regions are removed using a selective etching process that removes the unprotected regions. The etch process may include a direction etch process, such as reactive ion etching (RIE). The etch process applied to the channel layers 11 can provide the geometry for the stack of channels 27.

Still referring to FIG. 6, an interlevel dielectric material 37 may be deposited and then etched using an isotropic etch back process to fill the space between two patterned columns that provide the stack of channels 27.

FIG. 7 is a side cross-sectional view along section line Y1-Y1 depicting forming a backside interface layer 9, in accordance with an embodiment of the present invention. In an embodiment, forming the backside interface layer 9 may include removing the first sacrificial sheet 13. In some examples, the first sacrificial sheet 13 may be removed by an etch that is selective to the second sacrificial sheets 12 and the channel layers 11. As used herein, the term “selective” in reference to a material removal process denotes that the rate of material removal for a first material is greater than the rate of removal for at least another material of the structure to which the material removal process is being applied. For example, in an embodiment, a selective etch may include an etch chemistry that removes a first material selectively to a second material by a ratio of 10:1 or greater, e.g., 1000:1.

For example, an etch process may remove the silicon and germanium (SiGe) containing material having a germanium content of 55 wt. % of the first sacrificial sheet 13 without removing the silicon (Si) material that provides the channel layers 11, and without removing the second sacrificial sheets 12 including a composition of silicon and germanium (SiGe) having a germanium (Ge) content of 25%. In an embodiment, the first sacrificial sheet 13 may be removed by an isotropic etch, e.g., non-directional etch, such as a gas etch, or plasma etch.

FIG. 7 also illustrates filling the space that is formed by removing the first sacrificial sheet 13 with a dielectric material to provide the backside interface layer 9. The backside interface layer 9 is present between the upper semiconductor layer 4 and the channel at the base of the stack of channels 27. Forming the backside interface layer 9 may include a deposition and etch back process. For example, the backside interface layer 9 may have a dielectric material composition, such as silicon nitride or silicon oxide, and may be formed using a deposition process, such as chemical vapor deposition (CVD) or atomic layer deposition (ALD). The composition of the backside interface layer 9 may be selected to provide that a later-formed sacrificial inner spacer 60 and sacrificial gate sidewall spacer 61 may be removed using an etch that is selective to the backside interface layer 9.

In one example, the backside interface layer 9 may have a composition that includes silicon carbide (SiC). In some embodiments, following deposition of the material for the backside interface layer 9, an etch back process, such as reactive ion etching (RIE), may be employed to further tailor the geometry of the backside interface layer 9. The etch back process may include a direction etch, such as reactive ion etching (RIE). The hardmask 38 may be removed.

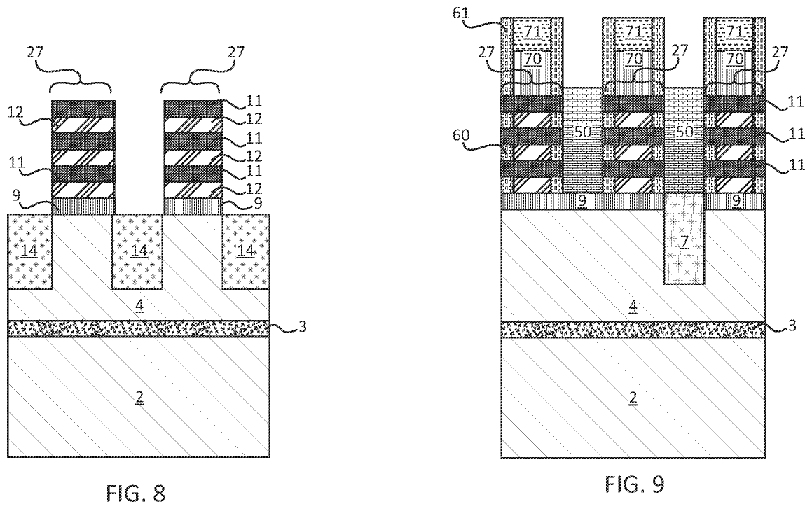

FIG. 8 is a side cross-sectional view along section line Y1-Y1 depicting deposition of an interlevel dielectric layer (ILD) on the structure depicted in FIG. 7 followed by a etch process to reveal the channel layers 11. In some embodiments, the process sequence can include depositing an interlevel dielectric layer followed by a planarization process, such as chemical mechanical planarization. An anisotropic etch may then be performed to recess the deposited dielectric to a height that provide at least one isolation region 14. The isolation region 14 separates portions of the upper semiconductor layer 4 that the stacks of the channel layers 11, the second sacrificial sheets 12 and the backside interface layer 9 are present on.

FIG. 9 is a side cross-sectional view that illustrates forming a replacement gate structure 70. As used herein, the term “replacement gate structure” denotes a sacrificial structure that dictates the geometry and location of the later formed functioning gate structure. The “functional gate structure” operates to switch the semiconductor device from an “on” to “off” state, and vice versa. In an embodiment, the sacrificial material that provides the replacement gate structure 70 may be composed of any material that can be etched selectively to at least the channel layers 11. In an embodiment, the sacrificial material of the replacement gate structure 70 may be composed of a silicon containing material, such as polysilicon. In another embodiment, the sacrificial material of the replacement gate structure may be composed of a dielectric material, such as an oxide or amorphous carbon. The replacement gate structure 70 may be formed using deposition (e.g., chemical vapor deposition) photolithography and etch processes (e.g., reactive ion etching).

In some embodiments, a mask structure 71 may be present atop the replacement gate structure 70. The mask structure 71 may be provided using deposition and photolithography steps, and may be employed in combinations with the directional, e.g., anisotropic, etch processes to shape the geometry of the replacement gate structure 70 that includes sacrificial material. Using the mask structure 71, the sacrificial material that provides the replacement gate structure 70 may be etched to provide the gate geometry using a directional etch process, such as reactive ion etching (RIE).

FIG. 9 also depicts an embodiment of forming a sacrificial gate sidewall spacer 61 and forming a sacrificial inner spacer 60. Forming the sacrificial inner spacer 60 can begin with forming a divot in the sidewall of the stacks of the channel layers 11 and the second sacrificial sheets 12. The divot may be formed by laterally etching the second sacrificial sheets 12 selectively to the channel layers 11. For example, an isotropic etch, such as a plasma etch or gas phase etch, may laterally etch the second sacrificial sheets 12 relative to the channel layers 11 forming a plurality of recesses or divots.

A dielectric material is then formed in the recesses or divots that have been formed on the sidewalls of the stack including the channel layers 11 and the second sacrificial sheets 12. The dielectric material is first deposited using a conformal deposition process filling the recesses or divots. The conformal deposition process for filling the divots may include chemical vapor deposition, such as plasma enhanced chemical vapor deposition or metal organic chemical vapor deposition. The dielectric material for filling the divots may also be deposited using atomic layer deposition (ALD). Thereafter, an etch back process is applied to remove the portions of the conformally deposited dielectric that are outside the divots, wherein the dielectric material that remains within the recesses and divots remains to provide the sacrificial inner spacers 60. The etch back process may include reactive ion etching. The sacrificial inner spacers 60 may be an oxide, nitride or oxynitride material.

In some embodiments, similar deposition and etch processes are used for forming the sacrificial gate sidewall spacer 61. The sacrificial gate sidewall spacer 61 is present on sidewalls of the replacement gate structure 70 that are overlying the stacks of the channel layers 11 and the second sacrificial sheets 12.

In some embodiments, multiple dielectric layers may be deposited to form the sacrificial inner spacer 60, and the sacrificial gate sidewall spacer 61. The deposition sequence and composition may be selected so that one of at least one the dielectric layers can be removed selectively to one of the dielectric layers that will remain in the voids created by removing portions of the sacrificial inner spacer 60 and the sacrificial gate sidewall spacer 61. In this embodiment, when the void is sealed, a portion of dielectric material may remain inside the airgap. This results in a composite airgap including a solid dielectric portion.

Referring to FIG. 9, in a following process step, using the mask structure 71 atop the replacement gate structure 70 and the sacrificial gate sidewall spacer 61 as an etch mask, trenches are formed through the backside interface layer 9 into the upper semiconductor layer 4 using an anisotropic etch. An epitaxial forming step is then used to deposit a semiconductor material in the trenches to produce a placeholder 7. An etch process, such as reactive ion etching, may be employed to tailor the height of the placeholder 7.

FIG. 9 also depicts forming the source/drain regions 50. In some embodiments, the source/drain regions 50 can be formed directly contacting the ends of the channel layers 11. The source/drain regions 50 may be formed by an epitaxial deposition method. In some embodiments, the epitaxial semiconductor material that provides the source/drain regions 50 may have a composition that includes silicon (Si), germanium (Ge), silicon germanium (SiGe), silicon doped with carbon (Si:C), or the epitaxial semiconductor material that provides the source and drain regions may have the composition of a type III-V compound semiconductor, such as gallium arsenide (GaAs).

In some embodiments, the source/drain regions 50 are formed from epitaxial semiconductor material that is doped to an n-type or p-type conductivity. In some embodiments, the epitaxial semiconductor material that provides the source/drain regions 50 has a composition of silicon (Si), germanium (Ge), silicon germanium (SiGe), silicon doped with carbon (Si:C) or the epitaxial semiconductor material has the composition of a type III-V compound semiconductor, such gallium arsenide (GaAs). The epitaxial semiconductor material for source/drain regions 50 may be in situ doped to a p-type or n-type conductivity. The term “in situ” denotes that a dopant, e.g., n-type or p-type dopant, is introduced to the base semiconductor material, e.g., silicon or silicon germanium, during the formation of the base material.

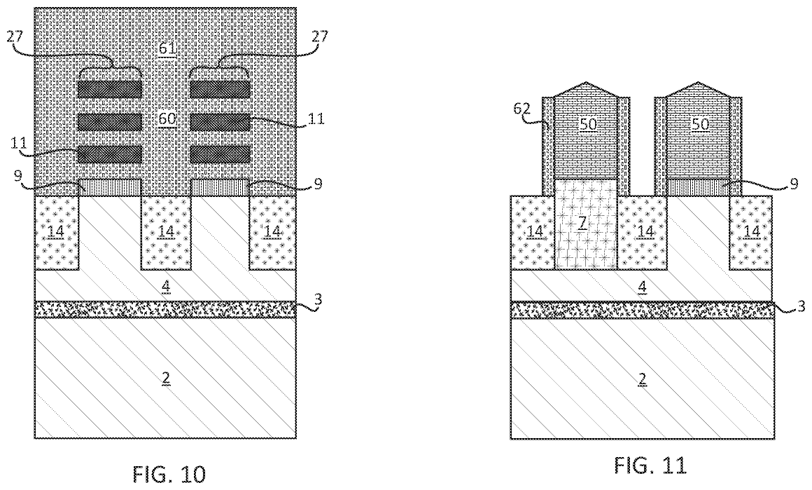

FIG. 10 is a side cross-sectional view along section line Y1-Y1 of the structure depicted in FIG. 9 illustrating the sacrificial inner spacer 60 and the sacrificial gate sidewall spacer 61. The portions of the sacrificial inner spacer 60 that are present between the depicted cross-sections of the channel layers 11 illustrate the portions of the sacrificial inner spacer 60 that are present in the divots.

FIG. 11 is a side cross-sectional view along section line Y2-Y2 of the structure depicted in FIG. 9 illustrating a sacrificial source/drain spacer 62. The lateral growth of the epitaxial material of the source/drain regions 50 is limited by the sacrificial gate sidewall spacer 61. The portions of the dielectric material for the sacrificial gate sidewall spacer 61 contact the face of the source/drain regions 50 to provide the sacrificial source/drain spacer 62. The epitaxial semiconductor material for the source/drain regions 50 is depicted abutting the sacrificial source/drain spacer 62.

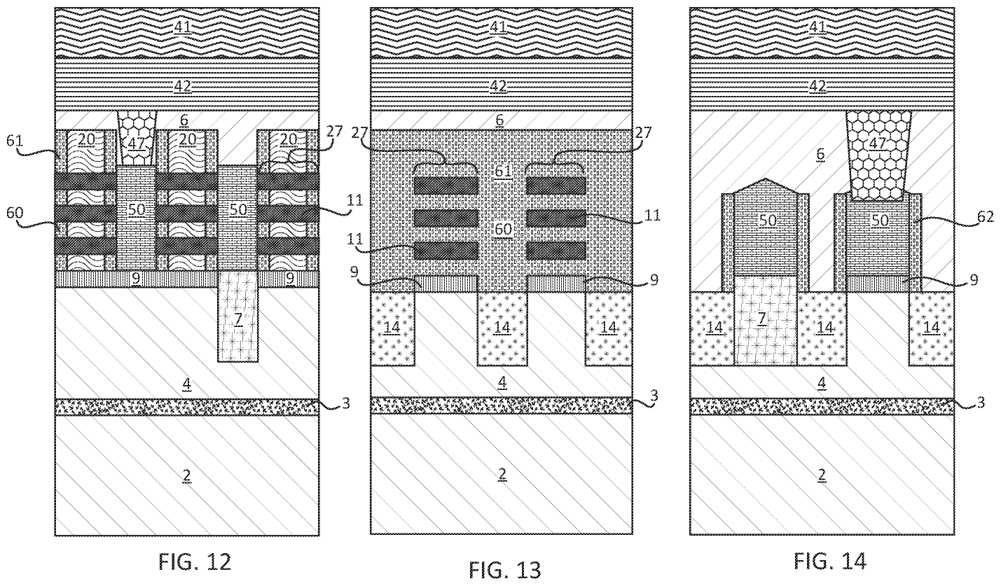

FIG. 12 depicts performing a replacement gate process to provide a gate structure 20 that is functional. Following the growth of the epitaxial semiconductor material for the source/drain regions 50, a frontside interlevel dielectric layer 6 is deposited and planarized. The frontside interlevel dielectric layer 6 may have a composition selected from the group consisting of silicon-containing materials such as SiO₂, Si₃N₄, SiOₓN_{y}, SiC, SiCO, SiCOH, and SiCH compounds; the above-mentioned silicon-containing materials with some or all of the Si replaced by Ge; carbon-doped oxides; inorganic oxides; inorganic polymers; hybrid polymers; organic polymers such as polyamides or SiLK™; other carbon-containing materials; organo-inorganic materials such as spin-on glasses and silsesquioxane-based materials; and diamond-like carbon (DLC, also known as amorphous hydrogenated carbon, α-C:H). The interlevel dielectric layer may be deposited using a deposition process, such as spin on deposition (SOD) followed by a planarization process, such as chemical mechanical planarization (CMP). The planarization process can continue until the mask structure 71 atop the replacement gate structure 70 is exposed.

The mask structure 71 and the replacement gate structure 70 can then be removed using a selective etch process without removing the semiconductor material of the channel layers 11. In some embodiments, once the replacement gate structure 70 is removed, the second sacrificial sheets 12 are removed by a selective etch, leaving the channel layers 11 suspended. The channel layers 11 may be supported by the sacrificial inner spacers 60. In some embodiments, the channel layers 11 may be further processed to provide reduced dimensions.

The replacement gate method can form a gate structure 20 that is functional in the space that was created by removing the replacement gate structure 70. The gate structure 20 includes a high-k gate dielectric and a metal gate conductor. The gate dielectric may be a high-k dielectric material, such as hafnium oxide (HfO₂). The gate dielectric for the gate all around structure may be deposited using chemical vapor deposition (CVD) or atomic layer deposition (ALD) and is present on the entirety of the exterior surfaces of the channel layers 11. The metal gate conductor for the gate structure 20 may encapsulate the channel layers 11 including the gate dielectric present on the exterior surfaces of the channel layers 11.

FIG. 12 shows middle of the line processing, back end of the line level processing and bonding a carrier wafer 41. The middle of the line processing may include forming the frontside contacts 47 to the source/drain regions 50 through the frontside interlevel dielectric layer 6. The frontside contact 47 extends metallization in the back end of the line level 42 to the source/drain regions 50. The back end of the line level 42 includes metal lines and vias that may be in electrical communication with the contacts produced in the middle of the line (MOL). The process sequence that is used for forming the metal lines and vias is a back end of the line (BEOL) process. In some embodiments, an interlevel dielectric layer is first deposited and then etched to form via openings to the underlying contacts. Thereafter, the via openings are then filled with an electrically conductive material, such as a metal, e.g., copper, to provide vias. Thereafter, a deposition, pattern and fill sequence is repeated to forms lines. This may be referred to as a single damascene method for forming lines and vias. However, dual damascene sequences are also applicable. The sequence of deposition, pattern and etch are repeated as many times as needed to form each level of metal lines and vias. The carrier wafer 41 provides support to the structure as the backside of the device is processed.

FIG. 13 is a side cross-sectional view along section line Y1-Y1 illustrating the sacrificial inner spacer 60 and the sacrificial gate sidewall spacer 61. The portions of the sacrificial inner spacer 60 that are present in the divots support the channel layers 11 during replacement gate processing.

FIG. 14 is a side cross-sectional view long section line Y2-Y2 illustrating the frontside contacts 47 to the source/drain regions 50 through the frontside dielectric layer 6. The sacrificial source/drain spacer 62 is present on the sidewalls of the source/drain regions 50.

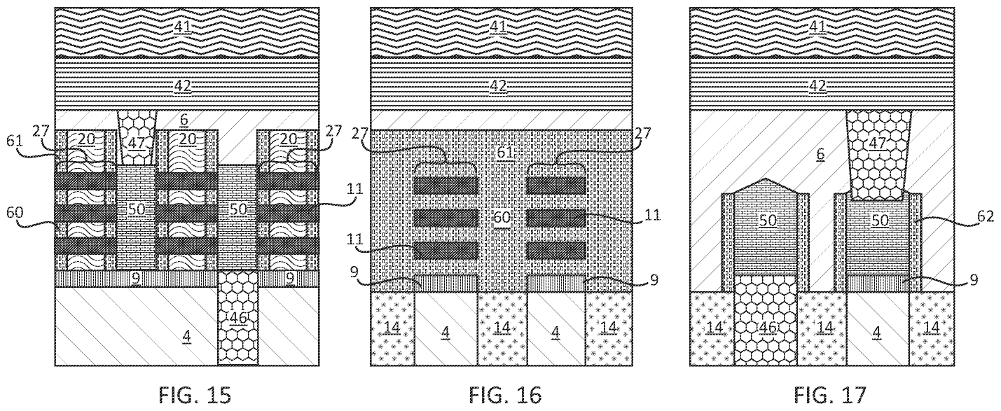

FIG. 15 is a side cross-sectional view along section line X1-X1 illustrating the formation of backside contacts 46 to source/drain regions 50. In an embodiment, forming the backside contacts 46 can begin with removing the substrate 2, the etch stop layer 3, as well as a portion of the upper semiconductor layer 4. These elements may be removed by selective etching. For example, the portions of the upper semiconductor layer 4 may then be removed by an etch process that is selective to the isolation regions 14. In some embodiments, the etch process may be an anisotropic etch, such as reactive ion etching (RIE).

FIG. 15 also illustrates an etch process to remove the placeholder 7 and to expose a backside of the source/drain regions 50. The placeholder 7 may be removed by a selective etch process. Thereafter, the opening that is produced by removing the placeholder 7 is filled with an electrically conductive material to provide the backside contact 46. The backside contacts 46 may include a metal, such as copper, aluminum, platinum, silver, gold, tungsten, and combinations thereof. The backside contacts 46 may be deposited using plating and/or physical vapor deposition (PVD). Following deposition, a planarization process may be performed, such as chemical mechanical planarization (CMP).

FIG. 16 is a side cross-sectional view along section line Y1-Y1 of the structure depicted in FIG. 15 illustrating the sacrificial inner spacer 60 present between individual channel layers 11 that overlay remaining portions of the upper semiconductor layer 4. The remaining portions of the upper semiconductor layer 4 are separated by isolation regions 14.

FIG. 17 is a side cross sectional view along section line Y2-Y2 of the structure depicted in FIG. 15, which shows the formation of the backside contact 46 to one of the source/drain regions 50. The source/drain region 50 contacted by the backside contact 46 in FIG. 17 is not in direct contact with the frontside contact 47.

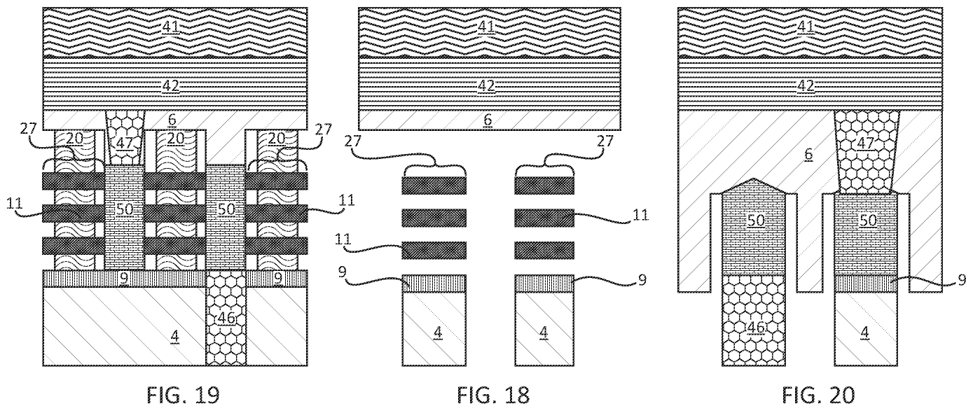

FIG. 18 is a side cross-sectional view along section line Y1-Y1 depicting the removal of the sacrificial inner spacer 60 and the sacrificial gate sidewall spacer 61, in accordance with an embodiment of the present invention. In some embodiments, removing the sacrificial inner spacer 60 and the sacrificial gate sidewall spacer 61 may begin with removing the isolation regions 14. The isolation regions 14 may be removed by an etch that is selective to the upper semiconductor layer 4 and the backside interface layer 9. In a following etch process, the sacrificial inner spacer 60 and the sacrificial gate sidewall spacer 61 may be removed by an etch that is selective to at least the backside interface layer 9. In an embodiment, the sacrificial inner spacer 60 and the sacrificial gate sidewall spacer 61 may be removed by an isotropic etch, e.g., non-directional etch, such as a gas etch, or plasma etch. Removing the sacrificial inner spacer 60 and the sacrificial gate sidewall spacer 61 provides an empty space that is subsequently sealed to provide airgaps.

In some embodiments, at least a portion of the dielectric material of the sacrificial inner spacer 60 and the sacrificial gate sidewall spacer 61 can remain within the void produced during the etch step that removes the majority of the sacrificial inner spacer 60 and the sacrificial gate sidewall spacer 61.

FIG. 19 is a side cross-sectional view along section line X-X illustrating removing the sacrificial inner spacer 60 and the sacrificial gate sidewall spacer 61. The etch process for removing the sacrificial inner spacer 60 and the sacrificial gate sidewall spacer 61 does not remove the backside interface layer 9.

FIG. 20 is a side cross-sectional view along section line Y2-Y2 of the structure depicted in FIG. 18 depicting removing the sacrificial source/drain spacer 62. The sacrificial source/drain spacer 62 can be removed by the same etch process that removes the sacrificial inner spacer 60 and the sacrificial gate sidewall spacer 61. The selective etch process for removing the sacrificial source/drain spacer 62 does not remove the backside contact 46 or the remaining portion of the upper semiconductor layer 4.

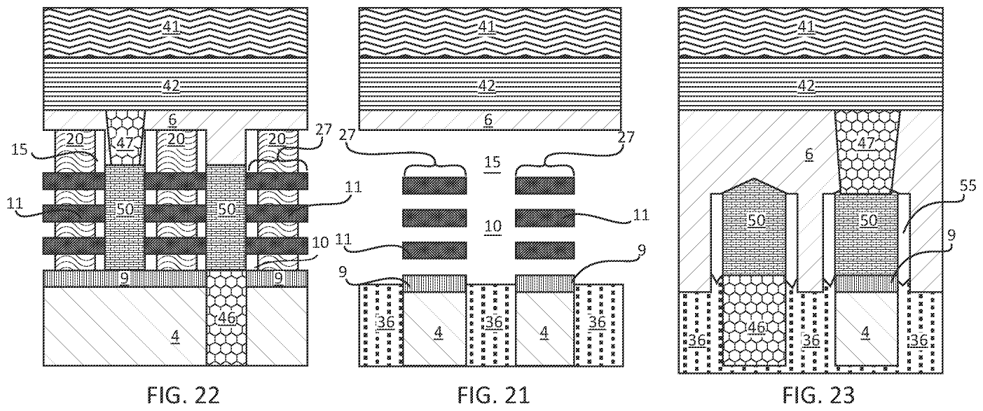

FIG. 21 is a side cross-sectional view along section line Y1-Y1 showing the deposition of a sealing dielectric 36 to seal openings to the inner airgap spacer 10 and gate sidewall airgap spacer 15. The sealing dielectric 36 closes the openings present through the portions of the upper semiconductor layer 4 that remain after the isolation regions 14 are removed. The sealing dielectric 36 encloses the void that was produced by removing the sacrificial inner spacer 60 and by removing the sacrificial gate sidewall spacer 61 producing the inner airgap spacer 10 and gate sidewall airgap spacer 15. In some examples, the sealing dielectric 36 may be an oxide, nitride or oxynitride material. However, the sealing dielectric 36 may be provided by any dielectric composition. The sealing dielectric 36 may be deposited using chemical vapor deposition or spin on deposition.

FIG. 22 is a side cross-sectional view along section line X-X illustrating the inner airgap spacer 10 and gate sidewall airgap spacer 15 following sealing with the sealing dielectric 36 depicted in FIG. 21.

FIG. 23 is a side cross-sectional view along section line Y2-Y2 depicting sealing the source/drain airgap spacer 55. The sealing dielectric 36 fills the space between the backside contact 46 and remaining portions of the upper semiconductor layer 4, which seals the void that was provided by removing the sacrificial source/drain spacer 62.

In some embodiments, in which a portion of the sacrificial inner spacer 60 and the sacrificial gate sidewall spacer 61 remain within the voids produced by removing the majority of these elements, sealing the openings to the voids with the dealing dielectric 36 can encapsulate any remaining portions of the sacrificial inner spacer 60 and the sacrificial gate sidewall spacer 61 within the airgaps. This results in a composite airgap including a solid dielectric portion.

The process continues leading up to forming the backside power distribution network 43 resulting in the final device structure depicted in FIGS. 2-4.

FIG. 2 is a side cross-sectional view along section line X-X illustrating removing the remaining portions of the upper semiconductor layer 4 with an etch that is selective to the sealing dielectric 36, the backside contact 46 and the backside interface layer 9. Thereafter, a backside interlevel dielectric layer 34 is formed. The backside interlevel dielectric layer 34 is formed in direct contact with the backside interface layer 9. FIG. 2 also depicts the buried power rail 44 in contact with the backside contact 46.

FIG. 3 is a side cross-sectional view along section line Y1-Y1. FIG. 3 illustrates forming a power rail interlevel dielectric layer 51. The power rail interlevel dielectric layer 51 is deposited and etched to provide trenches for the buried power rail 44. The buried power rail 44 is formed in the trenches positioned in the power rail interlevel dielectric layer 51 using a metal deposition process followed by planarization.

FIG. 4 is a side cross-sectional view along section line Y2-Y2 illustrating the backside power distribution network 43 in contact the backside contact 46. The backside power distribution network 43 is formed with a deposition, pattern and fill sequence that is repeated to form metal lines and via in levels of interlevel dielectrics. The backside power distribution network 43 may be formed using a single damascene method for forming the metal lines and vias. However, dual damascene sequences are also applicable. The sequence of deposition, pattern and etch processes can be repeated as many times as needed to form each level of the metal lines and vias in the backside power distribution network 43.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment. For purposes of the description hereinafter, the terms “upper”, “over”, “overlying”, “lower”, “under”, “underlying”, “right”, “left”, “vertical”, “horizontal”, “top”, “bottom”, and derivatives thereof shall relate to the embodiments of the disclosure, as it is oriented in the drawing figures. The term “positioned on” means that a first element, such as a first structure, is present on a second element, such as a second structure, wherein intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

Having described preferred embodiments of a methods and structures for an airgap spacer with backside power delivery, it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

What is claimed is:

1. A semiconductor device comprising:
a gate structure on a stack of channel layers;
a source/drain region adjacent to the stack of channel layers;
an inner airgap spacer positioned between channels in the stack of channel layers, wherein the inner airgap spacer separates the gate structure from the source/drain region; and
a backside interface layer across a base of the inner airgap spacer.

2. The semiconductor device of claim 1, wherein the gate structure is a gate all around gate structure.

3. The semiconductor device of claim 1, wherein a first side of the inner airgap spacer is in contact with the gate structure, and a second side of the inner airgap spacer is in contact with the source/drain region.

4. The semiconductor device of claim 1, wherein the source/drain region is contacted by a frontside contact.

5. The semiconductor device of claim 1, wherein the source/drain region is contacted a backside contact to a backside power distribution network.

6. A semiconductor device comprising:
a gate structure on a stack of channel layers;
a source/drain region adjacent to the stack of channel layers;
an inner airgap spacer positioned between channels in the stack of channel layers, wherein the inner airgap spacer separates the gate structure from the source/drain region;
a backside interface layer across a base of the inner airgap spacer; and
a gate sidewall airgap spacer present on a sidewall of the gate structure that is overlying the inner airgap spacer.

7. The semiconductor device of claim 6, wherein the gate structure is a gate all around gate structure.

8. The semiconductor device of claim 6, wherein a first side of the inner airgap spacer is in contact with the gate structure, and a second side of the inner airgap spacer is in contact with the source/drain region.

9. The semiconductor device of claim 6, wherein the source/drain region is contacted by a frontside contact.

10. The semiconductor device of claim 6, wherein the source/drain region is contacted by a backside contact to a backside power distribution network.

11. A semiconductor device comprising:
a gate structure on a stack of channel layers;
a source/drain region adjacent to the stack of channel layers;
an inner airgap spacer positioned between channels in the stack of channel layers, wherein the inner airgap spacer separates the gate structure from the source/drain region;
a backside interface layer across a base of the inner airgap spacer; and
a source/drain airgap spacer present on a face of the source/drain region.

12. The semiconductor device of claim 11, wherein the gate structure is a gate all around gate structure.

13. The semiconductor device of claim 11, wherein a first side of the inner airgap spacer is in contact with the gate structure, and a second side of the inner airgap spacer is in contact with the source/drain region.

14. The semiconductor device of claim 11, wherein the source/drain region has a frontside contact.

15. The semiconductor device of claim 11, wherein the source/drain region has a backside contact to a backside power distribution network.

16. A semiconductor device comprising:
a gate structure on a stack of channel layers;
a source/drain region adjacent to the stack of channel layers;
an inner airgap spacer positioned between channels in the stack of channel layers, wherein the inner airgap spacer separates the gate structure from the source/drain region; and
a backside interface layer extending from a base surface of the stack of channel layers to a base surface of the source/drain region to encapsulate the inner airgap spacer.

17. The semiconductor device of claim 16, wherein the gate structure is a gate all around gate structure.

18. The semiconductor device of claim 16, wherein a gate sidewall airgap spacer is present on a sidewall of the gate structure that is overlying the inner airgap spacer.

19. The semiconductor device of claim 16, wherein the source/drain region has a backside contact to a backside power distribution network.

20. A semiconductor device comprising:
a gate structure on a stack of channel layers;
source/drain regions on opposing sides of the stack of channel layers;
inner airgap spacers positioned between channels in the stack of channel layers, wherein the inner airgap spacers separates the gate structure from the source/drain regions;
a backside interface layer extending from the stack of channel layers to a first of the source/drain regions across a base of the inner airgap spacers; and
a backside contact to a second of the source/drain regions.

21. The semiconductor device of claim 20, wherein the gate structure is a gate all around gate structure.

22. The semiconductor device of claim 20, wherein a gate sidewall airgap spacer is present on a sidewall of the gate structure that is overlying the inner airgap spacers.

23. The semiconductor device of claim 20, wherein a source/drain airgap spacer is present on a face of the source/drain regions.

24. The semiconductor device of claim 20, wherein the first of the source/drain regions has a frontside contact.

25. The semiconductor device of claim 20, wherein the backside contact is in contact with a backside power distribution network.
